(19) United States
(12) Patent Application Publication
(10) Pub. No.: US 2025/0360596 A1
(43) Pub. Date: Nov. 27, 2025

(54) CHEMICAL MECHANICAL POLISHING METHOD USING FOAMED SLURRY AND APPARATUS FOR FOAMED SLURRY GENERATION

(71) Applicant: Applied Materials, Inc., Santa Clara, CA (US)

(72) Inventors: Ekaterina MIKHAYLICHENKO, Santa Clara, CA (US); Brian J. BROWN, Palo Alto, CA (US)

(21) Appl. No.: 18/669,659

(22) Filed: May 21, 2024

(51) Int. Cl. B24B 57/02; B24B 37/04; H01L 21/306

(52) U.S. Cl. CPC B24B 57/02; B24B 37/044; H01L 21/30625

(57) ABSTRACT

Embodiments of the present disclosure generally relate to dispensing slurry as a foam in chemical mechanical polishing systems. A polishing apparatus includes a platen, a polishing pad having a polishing surface and disposed on the platen, a carrier head configured to press a substrate onto the polishing surface, a spray bar assembly configured to dispense a polishing foam onto the polishing surface, and a controller coupled to the polishing apparatus and configured to cause the polishing apparatus to: place a substrate on the polishing surface using the carrier head, create a polishing foam using a polishing liquid, a surfactant, and a gas using the spray bar assembly, use the spray bar assembly to dispense the polishing foam onto the polishing pad, and rotate the polishing pad using the platen to polish the substrate.

### BACKGROUND

### Field

Embodiments of the present disclosure generally relate to chemical mechanical polishing (CMP) systems used in the manufacturing of semiconductor devices. In particular, embodiments herein relate to dispensing slurry in CMP systems.

### Description of the Related Art

Integrated circuits are typically formed on substrates, particularly silicon wafers, by the sequential deposition of conductive, semiconductive, or insulative layers. After each layer is deposited, the layer is etched to create circuitry features. As a series of layers are sequentially deposited and etched, the exposed surface of the substrate becomes successively less planar. This non-planar outer surface presents a problem for the integrated circuit manufacturer as a non-planar surface can prevent proper focusing of a photolithography apparatus in subsequent processes. Therefore, there is a need to periodically planarize the substrate surface to provide a planar surface.

Chemical mechanical polishing (CMP) is one accepted method of planarization that typically requires that the substrate be mounted on a carrier or polishing head. The substrate is then placed against a rotating polishing pad. The carrier head may also rotate or oscillate to provide additional motion between the substrate and polishing surface. Further, a polishing liquid or slurry, which may include an abrasive and at least one chemically reactive agent, may be spread on the polishing pad.

However, a significant amount of slurry can be wasted during CMP. The slurry is continuously supplied over the polishing pad which can lead to a considerable amount of slurry being used, with a substantial portion of the slurry not being effectively utilized in the planarization process.

Accordingly, there is a need for improved systems and methods of chemical mechanical polishing to reduce slurry waste.

### SUMMARY

Embodiments of the present disclosure generally relate to chemical mechanical polishing (CMP) systems used in the manufacturing of semiconductor devices. In particular, embodiments herein relate to dispensing slurry as a foam in CMP systems.

In an embodiment, a polishing apparatus is provided. The polishing apparatus includes a platen, a polishing pad having a polishing surface and disposed on the platen, a carrier head configured to press a substrate onto the polishing surface, a spray bar assembly configured to dispense a polishing foam onto the polishing surface, and a controller coupled to the polishing apparatus and configured to cause the polishing apparatus to: place a substrate on the polishing surface using the carrier head, create a polishing foam using a polishing liquid, a surfactant, and a gas using the spray bar assembly, use the spray bar assembly to dispense the polishing foam onto the polishing pad, and rotate the polishing pad using the platen to polish the substrate.

In another embodiment, a spray bar assembly is provided. The spray bar assembly includes a dispense arm, a polishing liquid supply line routed along the dispense arm, a surfactant supply line, a gas supply line, a foam sprayer nozzle assembly comprising a nozzle body and coupled to the polishing liquid supply line, the surfactant supply line, and the gas supply line, the foam sprayer nozzle assembly configured to dispense a polishing foam on a polishing pad, and a controller coupled to the spray bar assembly and configured to cause the spray bar assembly to: create a polishing foam using a polishing liquid, a surfactant, and a gas using the foam sprayer nozzle assembly, and dispense, using the dispense arm, the polishing foam onto a polishing pad.

In yet another embodiment, a method of polishing a substrate is provided. The method includes placing a substrate on a polishing pad of a polishing apparatus, creating a polishing foam using a polishing liquid, a surfactant, and a gas, dispensing the polishing foam onto the polishing pad, and rotating the polishing pad to polish the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1A is a plan view of a polishing apparatus, according to certain embodiments.

FIG. 1B is a schematic, partial cross-sectional side view of the polishing apparatus of FIG. 1A, according to certain embodiments.

FIG. 2 illustrates a sectional view of a polishing liquid delivery system of a polishing apparatus, according to certain embodiments.

FIG. 3 illustrates a foam sprayer nozzle assembly configured to produce a polishing foam, according to certain embodiments.

FIG. 4 illustrates a foam sprayer nozzle assembly configured to produce a polishing foam, according to certain embodiments.

FIG. 5 illustrates a flow chart of a method of polishing a substrate using a polishing foam, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to chemical mechanical polishing (CMP) systems used in the manufacturing of semiconductor devices. In particular, embodiments herein relate to dispensing slurry as a foam in CMP systems.

Chemical Mechanical Polishing (CMP) is a process used in the semiconductor manufacturing to planarize surfaces with the combination of chemical and mechanical forces. The process uses an abrasive and corrosive polishing liquid or slurry, commonly a colloid, in conjunction with a polishing pad and retaining ring. The pad and substrate are pressed together by a polishing head and held in place by a retaining ring. The polishing head is rotated with different axes of rotation to remove material and even out any irregular topography, making the substrate flat or planar.

In a CMP setup, a slurry introduction mechanism deposits the slurry on the pad. Both the plate and the carrier are then rotated, and the carrier is kept oscillating. A downward pressure or down force is applied to the carrier, pushing it against the pad.

A significant amount of slurry can be wasted during CMP. The slurry is continuously supplied over the polishing pad during the process, e.g., while the polishing pad is rotating, which leads to a considerable amount of slurry being used, and not all of it is effectively utilized in the planarization process. The slurry significantly impacts the material removal rate, the planarization rate, and the surface quality of the polished substrate. Therefore, improving the use of slurry is not only reduces waste, but also maintains the effectiveness of the CMP process.

The present disclosure provides a system and apparatus to produce a slurry foam to reduce slurry waste during CMP processes. In particular, the present disclosure provides for a polishing liquid delivery arm with at least one foam sprayer nozzle assembly. The foam sprayer nozzle assembly includes a foam nozzle body coupled to a slurry or polishing liquid supply line, a surfactant supply line, and a gas line. The polishing liquid, surfactant, and gas mix within the foam nozzle body to produce a polishing foam which is expelled onto a substrate. This system replaces the liquid slurry with a foam slurry that has increased viscosity that remains on a substrate, due to the non-Newtonian behavior of foam, as the substrate rotates during polishing in a CMP system. The use of the polishing foam reduces polishing liquid waste as more slurry remains on the surface of the substrate.

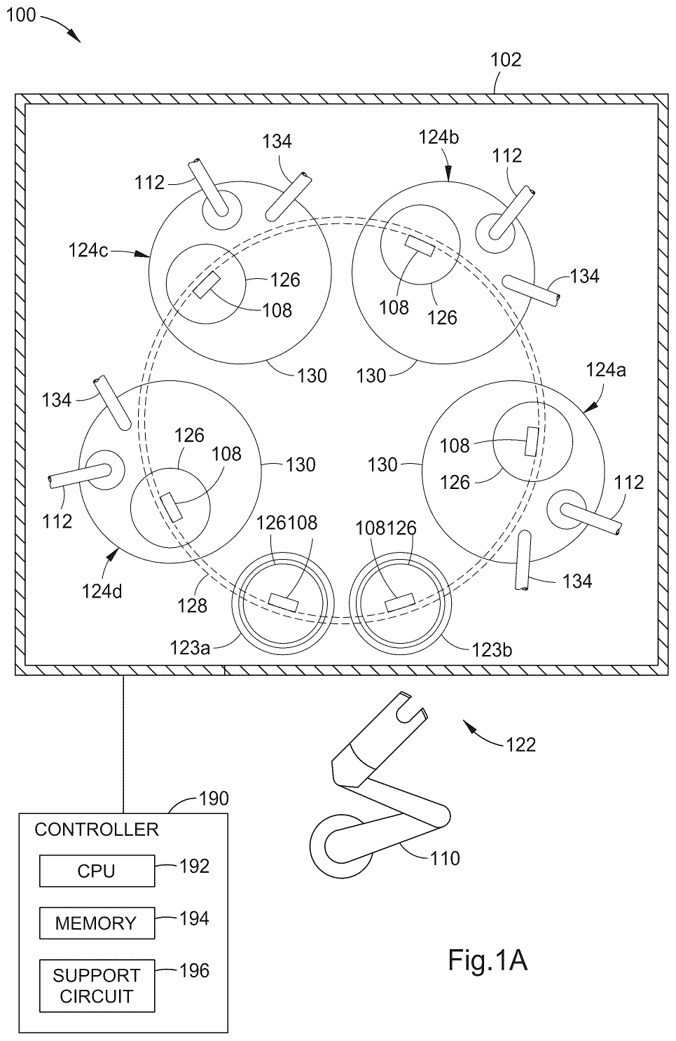

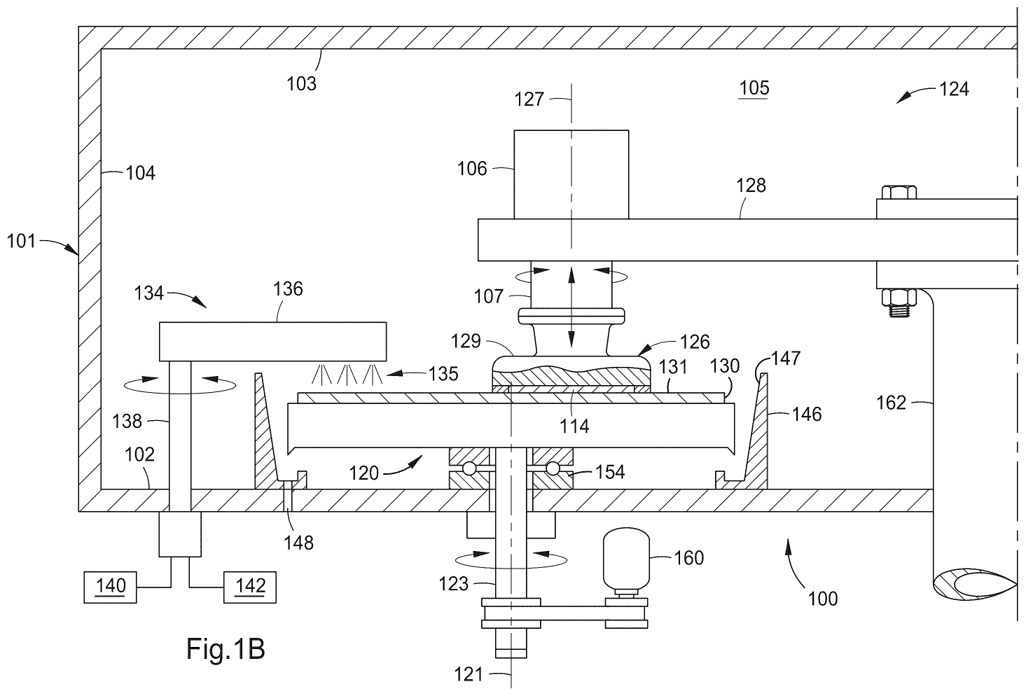

FIG. 1A is a plan view of a polishing apparatus 100, such as a chemical mechanical polishing (CMP) tool for processing one or more substrates. The polishing apparatus 100 includes a polishing platform, or base 102 that at least partially supports and houses a plurality of polishing stations 124. For example, the polishing apparatus 100 shown includes four polishing stations 124a, 124b, 124c and 124d. Each polishing station 124 is adapted to polish a substrate that is retained in a carrier head 126.

The polishing apparatus 100 also includes a plurality of carrier heads 126, each of which is configured to carry a substrate. The number of carrier heads can be a number equal to or greater than the number of polishing stations, e.g., four carrier heads or six carrier heads. For example, the number of carrier heads can be two greater than the number of polishing stations. This permits loading and unloading of substrates to be performed from two of the carrier heads while polishing occurs with the other carrier heads at the remainder of the polishing stations, thereby providing improved throughput.

The polishing apparatus 100 also includes a transfer station 122 for loading and unloading substrates from the carrier heads 126. The transfer station 122 can include a plurality of load cups 123, e.g., two load cups 123a and 123b, adapted to facilitate transfer of a substrate between the carrier heads 126 and a factory interface (not shown) or other device (not shown) by a transfer robot 110. The load cups 123 generally facilitate transfer between the transfer robot 110 and each of the carrier heads 126.

The stations of the polishing apparatus 100, including the transfer station 122 and the polishing stations 124, can be positioned at substantially equal angular intervals around the center of the base 102. This is not required, but can provide the polishing apparatus 100 with a reduced footprint.

Each polishing station 124 includes a polishing pad 130 supported on a platen 120 (shown in FIG. 1B). For a polishing operation, one carrier head 126 is positioned at each polishing station 124. Two additional carrier heads can be positioned in the transfer station 122 to exchange polished substrates for unpolished substrates while the other substrates are being polished at the polishing stations 124.

The carrier head 126 is adapted to hold a substrate against a polishing surface of the polishing pad 130, while relative motion is provided between the carrier head 126 and the platen 120 to polish the substrate. The relative motion may be rotational, lateral, or some combination thereof, and is provided by at least one of the carrier head 126 and the platen 120. Each carrier head 126 can have independent control of the polishing parameters, for example pressure, associated with each respective substrate.

The carrier heads 126 are held by a support structure that can cause each carrier head to move along a path that passes, in order, the first polishing station 124a, the second polishing station 124b, the third polishing station 124c, and the fourth polishing station 124d. This permits each carrier head to be selectively positioned over each of the polishing stations 124 and load cups 123.

In some implementations, each carrier head 126 is coupled to a carriage 108 that is mounted to an overhead track 128. By moving a carriage 108 along the overhead track 128, the respective carrier head 126 can be positioned over a selected polishing station 124 or load cup 123. A carrier head 126 that moves along the overhead track 128 traverses the path past each of the polishing stations 124.

In the implementation shown in FIG. 1A, the overhead track 128 has a circular configuration (shown in phantom) which allows the carriages 108 retaining the carrier heads 126 to be selectively orbited over and/or clear of the load cups 123 and the polishing stations 124. The overhead track 128 may have other configurations including elliptical, oval, linear or other suitable orientation. Alternatively, in some implementations (not shown) the carrier heads 126 are suspended from a carousel, and rotation of the carousel moves all of the carrier heads 126 simultaneously along a circular path. Although the polishing apparatus illustrated herein is outfitted with an overhead track, the present disclosure may utilize any suitable polishing apparatus. In one example, the polishing apparatus may have a robot which provides the same functionality as the overhead track.

Each polishing station 124 of the polishing apparatus 100 includes a spray bar assembly 134 configured to dispense polishing foam, such as abrasive slurry foam, onto the polishing pad 130 as shown in more detail in FIG. 1B. Each polishing station 124 of the polishing apparatus 100 includes a pad conditioning apparatus 112 to abrade the polishing surface 131 of the polishing pad 130 to maintain the polishing pad 130 in a consistent abrasive state.

The polishing foam dispensed from the spray bar assembly 134 may include several components. For example, the polishing foam may include abrasive particles, such as silica, alumina, or ceria, to provide a mechanical force for the polishing process. The polishing foam may include oxidizers, such as hydrogen peroxide (H₂O₂) and ozone (O₃), to react with the substrate surface to form a thin layer of oxidized material, which is then removed by the abrasive particles. Further, the polishing foam may include chelating agents, such as acetic acid, glycine, ethylene diamine, succinic acid, alanine and amino butyric acid (ABA), to bind to metal ions on the substrate surface, making the metal ions easier to remove. The polishing foam may include, for example, corrosion inhibitors, such as benzotriazole (BTA), 5-aminotetrazole monohydrate (ATA), 5-phenyl-1H-tetrazole (PTA), and 1-phenyl-1H-tetrazole-5-thiol (PTT), to prevent the substrate surface from corroding during the CMP process. The polishing foam may also include pH adjusters, such as tetramethylammonium hydroxide, to control the pH of the polishing foam, which affects the rate of chemical reactions during the CMP process. Additionally, the polishing foam may include dispersants and polymeric additives keep the abrasive particles dispersed evenly throughout the polishing foam.

A controller 190, such as a programmable computer, is connected to respective motors to independently control the rotation rate of the platen 120 and the carrier heads 126 as described in more detail below. For example, each motor can include an encoder that measures the angular position or rotation rate of the associated drive shaft. Similarly, the controller 190 is connected to an actuator in each carriage 108 to independently control the lateral motion of each carrier head 126. For example, each actuator can include a linear encoder that measures the position of the carriage 108 along the overhead track 128.

The controller 190 includes a programmable central processing unit (CPU) 192, which is operable with a memory 194 (e.g., non-volatile memory) and support circuits 196. The support circuits 196 are conventionally coupled to the CPU 192 and comprise cache, clock circuits, input/output subsystems, power supplies, and the like, and combinations thereof coupled to the various components of the polishing apparatus 100.

In some embodiments, the CPU 192 is one of any form of general purpose computer processor used in an industrial setting, such as a programmable logic controller (PLC), for controlling various monitoring system component and sub-processors. The memory 194, coupled to the CPU 192, is non-transitory and is typically one or more of readily available memory such as random access memory (RAM), read only memory (ROM), floppy disk drive, hard disk, or any other form of digital storage, local or remote.

The memory 194 may be in the form of a computer-readable storage media containing instructions (e.g., non-volatile memory), that, when executed by the CPU 192, facilitates the operation of the polishing apparatus 100. The instructions in the memory 194 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

Although illustrated as a single computer, the controller 190 could be a distributed system, e.g., including multiple independently operating processors and memories. The computer architecture is adaptable to various polishing operations based on programming of the controller 190 to control the order and timing that the carrier heads are positioned at the polishing stations.

For example, a mode of operation is for the controller to cause a substrate to be loaded into a carrier head 126 at one of the load cups 123, and for the carrier head 126 to be positioned in turn at each polishing station 124a, 124b, 124c and 124d so that the substrate is polished at each polishing station in sequence. After polishing at the last station, the carrier head 126 is returned to one of the load cups 123 and the substrate is unloaded from the carrier head 126.

FIG. 1B is a schematic, partial cross-sectional side view of FIG. 1A illustrating an exemplary spray bar assembly 134 in combination with polishing station 124. The polishing apparatus 100 has a housing 101. The housing 101 generally includes the base 102, an upper wall 103, and a sidewall 104 between the base 102 and the upper wall 103. The base 102, upper wall 103, and sidewall 104 define a processing region 105 of the polishing apparatus 100.

The carrier head 126 has a housing 129. The carrier head 126 is coupled to the overhead track 128 which is coupled to a column 162 and which extends over the platen 120. A drive system 106 is coupled the carrier head 126 by a drive shaft 107. The drive system 106 provides at least rotational motion to the carrier head 126. The drive system 106 may also provide lateral motion to the carrier head 126 to impart a sweeping motion to the carrier head 126 relative to the platen 120, e.g., by driving the carriage 108 on the overhead track 128. The carrier head 126 is actuatable toward and away from the platen 120 such that a substrate 114 retained in the carrier head 126 may be disposed against the polishing pad 130 during polishing.

The platen 120 at each polishing station 124 is rotatable about an axis 121. For example, a motor 160 turns a drive shaft 125 to rotate the platen 120. The platen 120 is rotationally disposed on the base 102. A bearing 154 is disposed between the platen 120 and the base 102 to facilitate rotation of the platen 120 relative to the base 102.

During operation, the platen 120 is rotated about axis 121, and each carrier head 126 is rotated about a respective axis 127 and translated laterally across the polishing surface 131. The lateral sweep is in a direction parallel to the polishing surface 131. The lateral sweep can be a linear or arcuate motion.

Each spray bar assembly 134 delivers polishing foam, such as polishing foam 135, to an associated polishing pad 130 to facilitate the substrate polishing operation. In addition, the spray bar assembly 134 can deliver a cleaning fluid, e.g., deionized water, to the polishing pad 130 to rinse polishing byproducts from the polishing surface 131. The spray bar assembly 134 includes an arm 136 having a plurality of fluid dispensing ports (not shown) in a distal end for spraying foam, such as polishing foam 135, onto the polishing surface 131 as shown in FIG. 1B. A proximal end of the arm 136 is coupled to a base 138 which extends upward from the base 102 of the housing 101. The base 138 is rotatable to pivot the arm 136 between a first position disposed over the platen 120 (shown in FIG. 1B) and a second position disposed adjacent the platen 120. During polishing, the spray bar assembly 134 is located in the first position and polishing foam 135 is applied onto the polishing surface 131 as the platen 120 rotates.

The spray bar assembly 134 is fluidly coupled to one or more fluid sources outside the processing region 105, such as polishing liquid source 140 and deionized water source 142. Although only slurry and deionized water sources are illustrated, the spray bar assembly 134 may utilize numerous additional fluid chemistries as known in the art. For example, other suitable fluid chemistries may include alcohols, amphiphilic compounds, acids (e.g., citric acid, hydrogen peroxide), bases, oxidizing agents, reducing agents, hydrophilic compounds, hydrophobic compounds (e.g., oils, fats, waxes), or mixtures thereof.

Each polishing station 124 of the polishing apparatus 100 includes a station cup 146 radially surrounding the platen 120. The station cup 146 has an inner sidewall surface 147 facing the platen 120. The inner sidewall surface 147 extends above the polishing surface 131. The polishing foam 135 from the polishing pad 130 contacts the inner sidewall surface 147 and collects inside the station cup 146. A drain 148 in the bottom of the station cup 146 and/or through the base 102 is used for draining the polishing foam 135 collected inside the station cup 146. De-foaming agents may be added to the drain flow to process the polishing foam 135 being drained from the polishing apparatus 100. De-foaming agents are typically insoluble in the foaming medium, e.g., the polishing liquid, and exhibit surface-active properties. For example, the de-foaming agents may be insoluble oils, silicones, alcohols, stearates, and glycols. Insoluble oils are often employed as de-foaming agents due to their ability to spread rapidly on foamy surfaces, destabilizing the foam lamellas, e.g., the bubble walls, leading to the bursting of gas bubbles and the breakdown of surface foam. Polydimethylsiloxanes and other silicones function similarly to insoluble oils, spreading quickly on foamy surfaces, destabilizing the foam lamellas, and causing the foam to collapse. Certain alcohols, stearates, and glycols can also serve as de-foaming agents, working by reducing the surface tension of the polishing liquid, which aids in breaking up the foam.

De-foaming agents function by entering the interface between the air and the foam lamellae. The de-foaming agents penetrates the bubble wall, which is bridged by the de-foaming agent droplet. This process, known as “bridging of the film,” thins the bubble wall. As the de-foaming agent spreads, it forms a lens on the lamella and begins to spread. This spreading process reduces the lens's thickness, which is altered by movements in the foam. Stresses occur until the lens breaks and the foam lamella ruptures.

The de-foaming agents may be injected directly into the drain flow, e.g., at the drain 148, or in the station cup 146 via nozzles (not shown). The de-foaming agents reduce the polishing foam 135 to liquid for easier processing post-CMP.

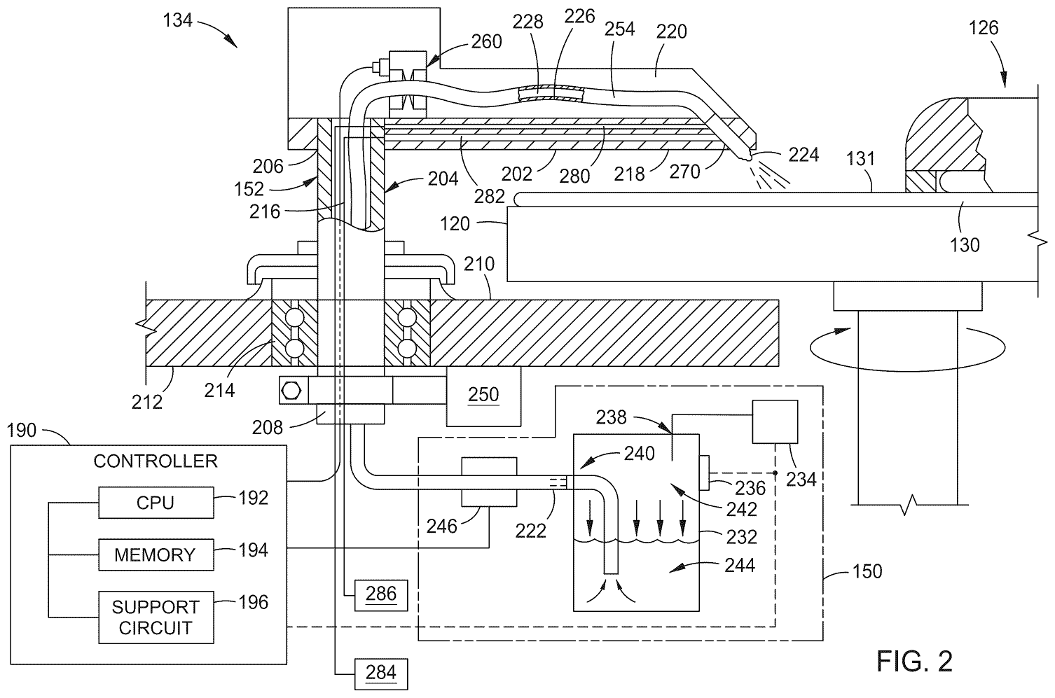

FIG. 2 depicts a sectional view of one embodiment of the spray bar assembly 134 of FIGS. 1A and 1B. The spray bar assembly 134 includes a dispense arm 202 affixed to and extending laterally from an upper portion 206 of a support member 204 above a top surface 210 of the base 102. A lower portion 208 of the support member 204 is rotatably mounted in and extends through a bottom 212 of the base 102. A bearing assembly 214 is disposed between the support member 204 and the base 102 to allow the dispense arm 202 extending from the upper portion 206 of the support member 204 to be rotated between a standby or purge position clear of the platen 120 and a dispense position over the polishing pad 130.

For simplicity in the embodiment depicted in FIG. 2, a single polishing liquid supply line 254 is shown routed along the dispense arm 202 for supplying polishing liquid to the polishing pad 130 disposed on the platen 120. However, any number of polishing liquid supply lines 254 may be utilized to supply polishing liquid from a common dispense arm 202 to a single platen 120. The polishing liquid supply line is comprised of a resilient and flexible material, such as silicone. The interior of the tube must be substantially free of interior anomalies.

In one embodiment, the polishing liquid supply line 254 is routed from an inlet end 222 coupled to a polishing liquid supply 150 through a passage 216 formed in the support member 204 and outward along a channel 220 disposed in the dispense arm 202. An outlet end 224 of the polishing liquid supply line 254 is positioned at a distal end 218 of the dispense arm 202. The distal end 218 includes a foam sprayer nozzle assembly 270 through which the outlet end 224 of the polishing liquid supply line 254 is disposed. The polishing liquid supply line 254 is secured to the foam sprayer nozzle assembly 270. In embodiments utilizing multiple polishing liquid supply lines 254, multiple foam sprayer nozzle assemblies 270 may be fixed to or positionable along the dispense arm 202, and have their outlet ends 224 grouped in a common location or spaced apart to dispense polishing foam at predefined locations across the diameter of the polishing pad 130.

In one embodiment, the polishing liquid supply line 254 is a single, continuous member running from its inlet end 222 to outlet ends 224. The polishing liquid supply line 254 has no crevasses, seams or other anomalies present along its inner surface 226 that would otherwise provide attachment points for abrasive or other particles that may be entrained or form in the polishing liquid, thereby advantageously decreasing the probability of particle agglomeration within the tube and there release to the polishing pad 130 where they may contact a substrate 114 being processed. The substantial elimination of release of agglomerated particles results in increased product yield by reducing scratching and substrate defects. Alternatively, the polishing liquid supply line 254 may be segmented, but with increased potential for diminished yield.

In one embodiment, the polishing liquid supply 150 includes a pressure vessel 232 and a pressure control system 234. The pressure vessel 232 contains a polishing liquid 244, and may be optionally coupled to a bulk supply system (not shown) for periodic replenishment of polishing liquid. The pressure vessel 232 has an inlet port 238 and outlet port 240. The inlet port 238 is coupled to the pressure control system 234 while the outlet port 240 is coupled to inlet end 222 of the polishing liquid supply line 254.

The pressure control system 234 generally controls the pressure within and/or delivers gas to the pressure vessel 232. Gas 242 within the pressure vessel 232 imparts a pressure on the polishing liquid 244 residing in the pressure vessel 232, thereby driving the polishing liquid 244 through the outlet port 240 and the polishing liquid supply line 254, and ultimately flowing out the outlet end 224 to the polishing pad 130. The pressure control system 234 may include regulators, pumps and the like to control the pressure applied to the polishing liquid 244 disposed in the pressure vessel 232. A pressure sensor 236 is coupled to the pressure vessel 232 to provide a metric indicative of the pressure within the pressure vessel 232.

A flow sensor 246 is interfaced with the polishing liquid supply line 254 to provide a metric indicative of the flow of polishing liquid passing therethrough. In embodiments where the polishing liquid supply line 254 is configured to flow fluids not prone to particle formation, for example de-ionized water and chemical reagents, flow sensors that engage the fluid, such as paddle wheels and the like may be utilized. In embodiments where the polishing liquid supply line 254 is configured to flow fluids containing particles and/or prone to particle formation, such as abrasive containing slurries, non-intrusive flow sensors, such as sonic flow transducers and the like may be utilized to maintain a continuous non-interrupted inner wall integrity of the polishing liquid supply line 254 between the polishing liquid supply 150 and the outlet end 224 of the polishing liquid supply line 254.

To enhance control over the polishing liquid flowing through the polishing liquid supply line 254, a restricting device 260 is utilized to interface with the polishing liquid supply line 254. As shown in FIG. 2, the restricting device 260 may be configured to apply a bias to the exterior of the polishing liquid supply line 254, resulting in a reduction of the interior sectional area 228 of the polishing liquid supply line 254 resulting in a flow restriction to the polishing liquid flowing therethrough. As the restricting device 260 is non-intrusive, i.e., does not create a seam in the flow path or otherwise contact the polishing liquid flowing through the tube, flow attributes, such as backpressure, which may be utilized to control the flow through the tube, may be controlled without creating surface conditions such as a seam that encourages the attachment and build-up of particles.

Moreover, as the restricting device 260 is configured to provide a variable restriction, the flow of polishing liquid through the polishing liquid supply line 254 to the polishing pad 130 may be controlled through a full range of flow conditions as desired. For example, the restricting device 260 may completely close the interior sectional area 228 of the polishing liquid supply line 254 resulting in zero polishing liquid flow. The restricting device 260 may also partially close the polishing liquid supply line 254 to a predefined percentage of the interior sectional area 228, or the restricting device 260 may leave the interior sectional area 228 of the polishing liquid supply line 254 substantially open in a full flow condition. One benefit of completely opening the polishing liquid supply line 254 to a full flow condition is that the increased flow rate through the polishing liquid supply line 254 sweeps any particles that may have attached to the tube walls or other components disposed in the polishing liquid flow path out of the polishing liquid supply line 254 during a purge cycle between polishing, thereby further reducing incidence of agglomerated particles reaching the substrate during processing.

In one embodiment, the pressure control system 234, the pressure sensor 236, flow sensor 246 and restricting device 260 are coupled to the controller 190 to allow closed loop control over the amount of polishing liquid flowing through the polishing liquid supply line 254. The controller 190 compares the sensed flow value resolved from the metric provided by the flow sensor 246 with a target value. In response, the controller 190 instructs at least one of the pressure within the pressure vessel 232 as controlled by the pressure control system 234 and the restriction or backpressure created by the restricting device 260 as controlled by the open area of the polishing liquid supply line 254 to be adjusted so that the sensed flow is maintained at substantially equal the target value.

The foam sprayer nozzle assembly 270 also includes a surfactant supply line 280 and a gas supply line 282. The surfactant supply line 280 is coupled to a surfactant source 284 configured to supply a surfactant at a surfactant flow rate to the foam sprayer nozzle assembly 270. Similarly, the gas supply line 282 is coupled to a gas source 286 configured to supply an inert gas, such as clean dry air or nitrogen gas (N₂), to the foam sprayer nozzle assembly 270. The surfactant supply line 280 and the gas supply line 282 in the foam sprayer nozzle assembly 270 allow the polishing pad 130 to deposit on the substrate 114 as a foam slurry rather than just a liquid.

The process of turning the polishing liquid into a foam uses a surfactant and includes several steps. Initially, a gas, such as clean dry air or nitrogen gas (N₂), and the polishing liquid are mixed together to form bubbles. The surfactant, which may be added before the polishing liquid is mixed with the gas or added while the mixture occurs, reduces the surface tension of the polishing liquid, which allows the polishing liquid to spread across the surface of the bubble. The reduction in surface tension facilitates the mixing of the gas and the polishing liquid. The surfactant also creates an elastic surface that enables the bubbles to withstand being bumped, squeezed, and deformed, improving the stability of the foam. Additionally, the surfactant creates a counter pressure, known as “disjoining pressure”, which acts against the capillary pressure that naturally pulls the polishing liquid out of the foam walls. The disjoining pressure can be produced by charges on the surfactant either side of the wall or by steric interactions between surfactant chains. The combination of reduced surface tension, elasticity, and disjoining pressure stabilize the foam. The foam becomes more stable as the surfactant concentration increases.

Surfactants supplied to the foam sprayer nozzle assembly 270 may be one of three types: anionic, nonionic, and cationic. Anionic surfactants carry a negative charge and include substances like sodium laureth sulfate (SLES), sodium lauryl sulfate (SLS), ammonium lauryl sulfate (ALS), ammonium laureth sulfate (ALES), sodium stearate, and potassium cocoate. Nonionic surfactants, which do not carry a charge, include ethoxylates, alkoxylates, and cocamides. Lastly, cationic surfactants carry a positive charge and substances include like quaternary ammonium salts, cetyltrimethylammonium bromide (CTAB), benzalkonium chloride (BAC), and dodecylbenzene sulfonic acid. The surfactant used to create a polishing foam depends on the chemistry of the polishing liquid and should be chosen so as to not alter the effectiveness of the polishing liquid.

The concentration of the surfactant as a weight percentage may be from about 0.01 wt % to about 5 wt %, such as about 0.05 wt % to about 2 wt %. The factors that determine the concentration of surfactants needed to generate the polishing foam include the Critical Micelle Concentration (CMC), the temperature of the CMP process, and pH of the polishing liquid. The CMC is the surfactant concentration at which micelles, e.g., aggregate surfactant molecules that stabilize a foam, start to form. Below this concentration, surfactant molecules remain soluble in water, while above it, micelles are present throughout the solution. Prior to reaching the CMC, the surface tension varies significantly with surfactant concentration. Upon reaching the CMC, the surface tension either remains relatively stable or changes at a reduced rate. The CMC value for a specific surfactant in a particular medium is influenced by temperature, pressure, and occasionally, the presence and concentration of other surface-active substances and electrolytes.

Additionally, the foaming capacity (FC) increases with higher foaming temperatures, while foam stability (FS) decreases as temperature rises. This behavior is attributed to the shortening of the half-life of the foam and the decrease in viscosity in the liquid phase as temperature increases. Anionic surfactants are less impacted by temperature and exhibit superior foaming ability and longer foam stability.

The pH of the polishing liquid can also affect the foaming properties of surfactants. Changes in pH alter the inter-molecular interactions of surfactants in the interfacial layers, thereby affecting interfacial network formation, dilatational visco-elasticity, and foaming properties. The most pronounced negative effect on polishing liquid foamability occurs at low pH levels, where the polymer charge density is the highest.

Producing the polishing liquid into a foam allows for improved polishing liquid use efficiency, e.g., less polishing liquid waste, due to the increased viscosity of the foam compared to its liquid form which allows for more of the polishing foam to remain on the substrate 114 as the substrate 114 rotates during processing.

The delivery arm assembly 152 additionally includes an actuator 250 coupled to the lower portion 208 of the support member 204 to control the angular orientation of the dispense arm 202. The actuator 250 may be a gear motor, a harmonic drive, a linear actuator, a motorized lead screw, a hydraulic cylinder, a pneumatic cylinder or other device suitable for imparting rotation to the dispense arm 202 about the support member 204. The actuator 250, in response to instructions from the controller 190, rotates the support member 204 and dispense arm 202, thereby controlling the position of the outlet end 224 of the polishing liquid supply line 254 over the polishing pad 130, for example, between a dispense position and a purge position. In this manner, the distribution of polishing liquid across the width of the polishing pad 130 may be controlled by adjusting the relative position of the outlet end 224 (i.e., dispense points) and the polishing pad 130. As the distribution of polishing liquid interfacing with the substrate on the polishing pad 130 is changed, the rate of material removal (e.g., polishing) may be controlled as desired. For example, more polishing liquid may be provided to the areas of the polishing pad 130 that predominantly contact the perimeter of the substrate, thereby polishing the perimeter of the substrate faster than the center.

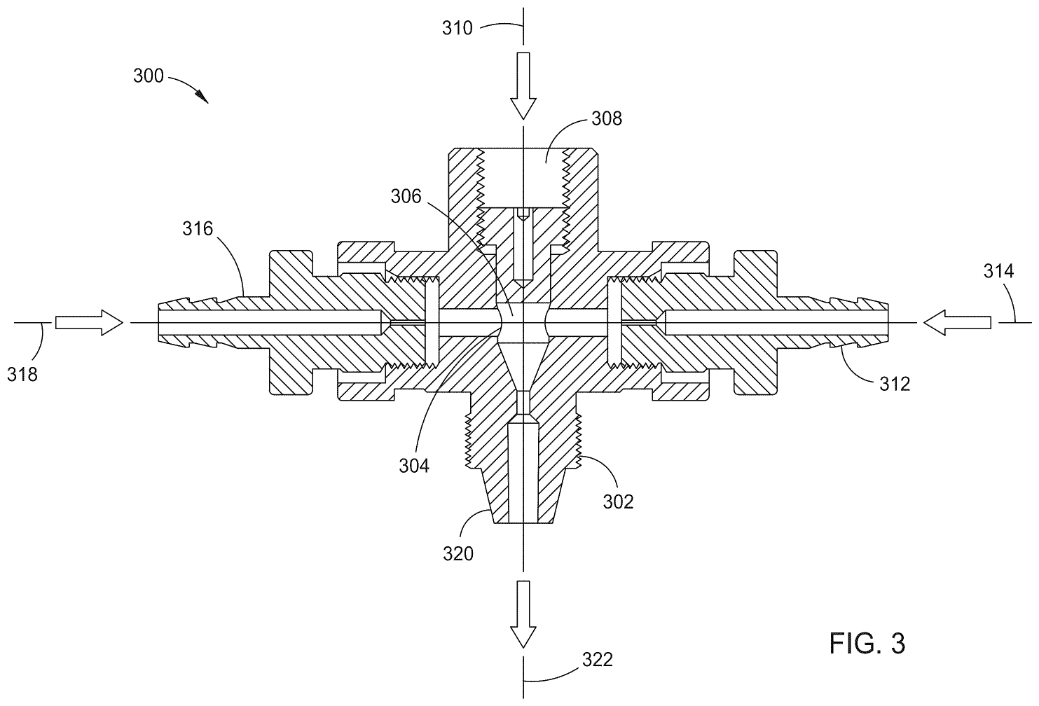

FIG. 3 illustrates a foam sprayer nozzle assembly 300 configured to produce a polishing foam using a polishing liquid, a surfactant, and a gas, according to certain embodiments. The foam sprayer nozzle assembly 300 may be used in the polishing apparatus of FIGS. 1A, 1B, and 2, e.g., as the foam sprayer nozzle assembly 270 of FIG. 2. As shown in FIG. 3, the foam sprayer nozzle assembly 300 includes a nozzle body 302 which may further include a four-way valve 304 disposed within an inner volume 306. The nozzle body 302 is coupled to a polishing liquid supply line 308 configured to supply a polishing liquid 310 to the inner volume 306. The polishing liquid 310 may include oxidizers, such as hydrogen peroxide (H₂O₂) and ozone (Os), to react with the substrate surface to form a thin layer of oxidized material, which is then removed by the abrasive particles. Further, the polishing liquid 310 may include chelating agents, such as acetic acid, glycine, ethylene diamine, succinic acid, alanine and amino butyric acid (ABA), to bind to metal ions on the substrate surface, making the metal ions easier to remove. The polishing liquid 310 may include, for example, corrosion inhibitors, such as benzotriazole (BTA), 5-aminotetrazole monohydrate (ATA), 5-phenyl-1H-tetrazole (PTA), and 1-phenyl-1H-tetrazole-5-thiol (PTT), to prevent the substrate surface from corroding during the CMP process. The polishing liquid 310 may also include pH adjusters, such as tetramethylammonium hydroxide, to control the pH of the polishing foam, which affects the rate of chemical reactions during the CMP process. Additionally, the polishing liquid 310 may include dispersants and polymeric additives keep the abrasive particles dispersed evenly throughout the polishing liquid 310. The nozzle body 302 is also coupled to a surfactant supply line 312 that is configured to supply a surfactant 314 to the inner volume 306. The surfactant 314 may include suitable substances, such as sodium laureth sulfate (SLES), sodium lauryl sulfate (SLS), ammonium lauryl sulfate (ALS), ammonium laureth sulfate (ALES), sodium stearate, potassium cocoate, ethoxylates, alkoxylates, cocamides, quaternary ammonium salts, cetyltrimethylammonium bromide (CTAB), benzalkonium chloride (BAC), and dodecylbenzene sulfonic acid. Additionally, the nozzle body 302 may be coupled to a gas supply line 316 configured to deliver a gas 318, such as clean dry air or nitrogen gas (N₂), to the inner volume 306 of the nozzle body 302.

In operation, the surfactant 314 is mixed with the polishing liquid 310 and the gas 318, and then is expelled out through a nozzle end 320 arranged in the four-way valve 304. When the mixture of the polishing liquid 310, the surfactant 314, and the gas 318 is exits the nozzle body 302, the mixture produces a polishing foam 322 having bubbles of the polishing liquid 310 encapsulating pockets of the gas 318. The polishing foam 322 allows for improved polishing liquid use efficiency, e.g., less polishing liquid waste, due to the increased viscosity of the foam compared to its liquid form which allows for more of the polishing foam to remain on a substrate as the substrate rotates during processing in a CMP system.

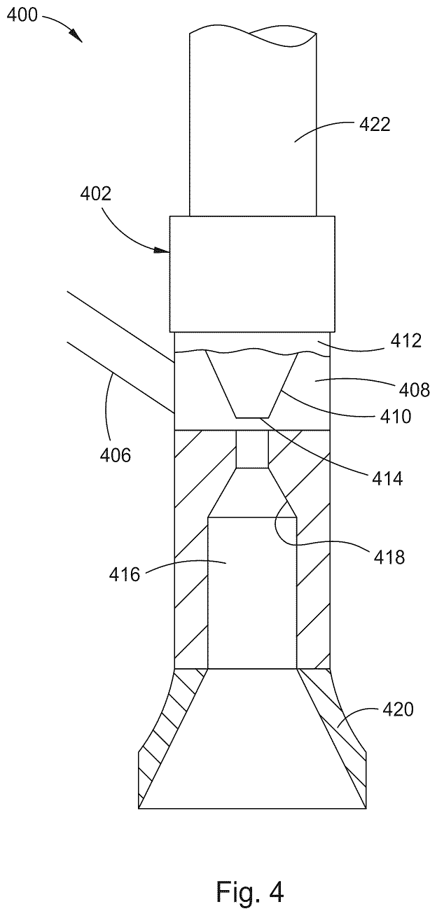

FIG. 4 illustrates a foam sprayer nozzle assembly 400 configured to produce a polishing foam using a polishing mixture that includes a polishing liquid and a surfactant, according to certain embodiments. The foam sprayer nozzle assembly 400 may be used in the polishing apparatus of FIGS. 1A, 1B, and 2, e.g., as the foam sprayer nozzle assembly 270 of FIG. 2. The nozzle body 402 is provided with a gas supply line 406 extending therethrough. The gas supply line 406 is adapted to receive the gas from a gas source (not shown). The gas supply line 406 terminates or opens into a vacuum chamber 408 formed in the nozzle body 402 and is configured to supply the gas to the vacuum chamber 408.

A venturi nozzle 410 is located at an inlet end 412 of the nozzle body 402. The venturi nozzle 410 is integrally formed as part of the inlet end 412 of the nozzle body 402. Alternatively, the venturi nozzle 410 may be separately manufactured and threadably secured to the inlet end 412 of the nozzle body 402. The venturi nozzle 410 tapers inwardly and terminates at a venturi distal end 414. The venturi distal end 414 of the venturi nozzle 410 extends into the vacuum chamber 408. The venturi distal end 414 is slightly spaced from the entrance of the fluid passage 416 extending through the nozzle body 402 downstream therefrom. The diameter and the cross-sectional area of the fluid passage 416 increases as it extends toward the outlet end of the nozzle body 402. A transmission zone in the fluid passage 416 is defined by the outwardly tapering circumferential wall 418.

A polishing mixture supply line 422 connects the nozzle body 402 to a polishing mixture source (not shown). The polishing mixture source contains a polishing mixture including a polishing liquid and a surfactant. The polishing mixture may include a plurality of surfactants configured to achieve a desired viscosity in a polishing foam. For example, the surfactant may include suitable substances, such as sodium laureth sulfate (SLES), sodium lauryl sulfate (SLS), ammonium lauryl sulfate (ALS), ammonium laureth sulfate (ALES), sodium stearate, potassium cocoate, ethoxylates, alkoxylates, cocamides, quaternary ammonium salts, cetyltrimethylammonium bromide (CTAB), benzalkonium chloride (BAC), and dodecylbenzene sulfonic acid. As the polishing mixture jets through the nozzle body 402, a vacuum is created in the vacuum chamber 408 due to the increased velocity of the polishing mixture exiting the venturi nozzle 410. The polishing mixture is accelerated through the reduced diameter of the fluid passage 416 at the entrance thereof. The velocity of the polishing mixture stream decreases as the fluid passage 416 expands. The fluid passage 416 provides a mixing chamber for the foam concentrate which is drawn into the polishing mixture stream by the reduced pressure in the vacuum chamber 408, thereby forming a foam spray exiting the nozzle end 420 of the nozzle body 402. Alternatively, a propellant, such as a hydrocarbon gas blend, may be used to generate the polishing foam. For example, the propellant may be mixed into a surfactant mixture to create fine bubbles when the mixture expands, e.g., in a nozzle body 402.

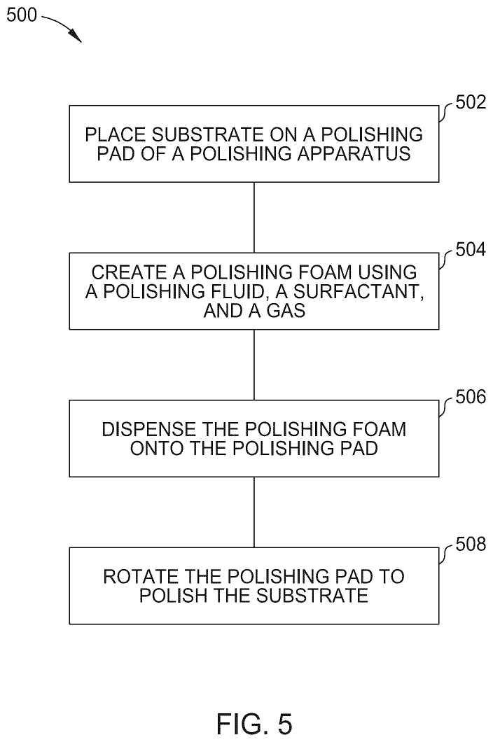

FIG. 5 illustrates a flow chart of a method 500 of polishing a substrate using a polishing foam, according to certain embodiments. The method 500 may be implemented using a controller, e.g., controller 190, of a polishing apparatus, e.g., polishing apparatus 100, and a foam sprayer nozzle assembly, e.g., the foam sprayer nozzle assembly 300. Although the foam sprayer nozzle assembly 300 of FIG. 3 is used to describe the method 500, it is contemplated that the foam sprayer nozzle assembly 400 of FIG. 4 may be used to implement the method 500.

The method 500 begins with operation 502 where a substrate 114 is placed on a polishing pad 130 of a polishing apparatus 100. The polishing pad 130 may be disposed on a platen 120 that may rotate. The substrate 114 may be held on a carrier head 126 and pressed onto a polishing surface 131 of the polishing pad 130.

In operation 504, a polishing foam 322 is created using a polishing liquid 310, a surfactant 314, and a gas 318, e.g., by spray bar assembly 134 of the polishing apparatus 100. The polishing foam 322 is created by mixing the polishing liquid 310, the surfactant 314, and the gas 318 to create bubbles of the gas 318 with bubble walls made of the polishing liquid 310, the surfactant 314, and any abrasive particles disbursed in the polishing liquid 310. The polishing foam 322 may be mixed using a foam sprayer nozzle assembly 300, where the polishing liquid 310, the surfactant 314, and the gas 318 are introduced into a nozzle body 302 by a polishing liquid supply line 308, a surfactant supply line 312, and a gas supply line 316, respectively. The mixture may exit as a foam through the nozzle body 302 at a nozzle end 320. Alternatively, the polishing liquid 310 and the surfactant 314 may be mixed before entering the nozzle body 302 and before exposure to the gas 318, as described regarding the foam sprayer nozzle assembly 400 of FIG. 4. Upon exiting the nozzle body 302, e.g., through nozzle end 320, the polishing foam 322 is dispensed on the polishing pad 130 in operation 506, e.g., while the spray bar assembly 134 is disposed over the polishing surface 131 of the polishing pad 130.

In operation 508, the polishing pad 130 is rotated to polish the substrate 114 using the polishing foam 322. For example, the platen 120 is rotated which rotates the polishing pad 130. The carrier head 126 holding the substrate 114 may press the substrate 114 onto the polishing surface 131 of the polishing pad 130 with the polishing foam 322 disposed thereon.

The present disclosure provides a system and apparatus to produce a slurry foam to reduce slurry waste during CMP processes. In particular, the present disclosure provides for a polishing liquid delivery arm with at least one foam sprayer nozzle assembly. The foam sprayer nozzle assembly includes a foam nozzle body coupled to a slurry or polishing liquid supply line, a surfactant supply line, and a gas line. The polishing liquid, surfactant, and gas mix within the foam nozzle body to produce a polishing foam which is expelled onto a substrate. This system replaces the liquid slurry with a foam slurry that has increased viscosity that remains on a substrate. The use of the polishing foam reduces slurry consumption and more efficient utilization of abrasive particles trapped at bubble walls of the slurry foam.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A polishing apparatus, comprising:
a platen;
a polishing pad having a polishing surface and disposed on the platen;
a carrier head configured to press a substrate onto the polishing surface;
a spray bar assembly configured to dispense a polishing foam onto the polishing surface; and
a controller coupled to the polishing apparatus and configured to cause the polishing apparatus to:
place a substrate on the polishing surface using the carrier head;
create a polishing foam using a polishing liquid, a surfactant, and a gas using the spray bar assembly;
use the spray bar assembly to dispense the polishing foam onto the polishing pad; and
rotate the polishing pad using the platen to polish the substrate.

2. The polishing apparatus of claim 1, wherein the spray bar assembly further comprises a polishing liquid supply line and a foam sprayer nozzle assembly coupled to the polishing liquid supply line, wherein the foam sprayer nozzle assembly comprises:
a nozzle body;
a surfactant supply line coupled to the nozzle body; and
a gas supply line coupled to the nozzle body.

3. The polishing apparatus of claim 2, wherein the polishing liquid, the surfactant, and the gas are configured to produce a polishing foam when mixed in an inner volume of the nozzle body.

4. The polishing apparatus of claim 2, wherein the gas supply line delivers nitrogen gas (N₂) to an inner volume of the nozzle body.

5. The polishing apparatus of claim 1, wherein the spray bar assembly further comprises a polishing mixture supply line and a foam sprayer nozzle assembly coupled to the polishing mixture supply line, wherein the foam sprayer nozzle assembly comprises:
a nozzle body; and
a gas supply line coupled to the nozzle body.

6. The polishing apparatus of claim 5, wherein the polishing mixture supply line delivers a polishing mixture including a polishing liquid and a surfactant configured to create a foam when mixed with the gas delivered by the gas supply line in an inner volume of the nozzle body.

7. The polishing apparatus of claim 5, wherein the gas supply line delivers nitrogen gas (N₂) to an inner volume of the nozzle body.

8. The polishing apparatus of claim 1, further comprising a station cup wherein a de-foaming agent is injected to reduce the polishing foam to a liquid.

9. A spray bar assembly, comprising:
a dispense arm;
a polishing liquid supply line routed along the dispense arm;
a surfactant supply line;
a gas supply line;
a foam sprayer nozzle assembly comprising a nozzle body and coupled to the polishing liquid supply line, the surfactant supply line, and the gas supply line, the foam sprayer nozzle assembly configured to dispense a polishing foam on a polishing pad; and
a controller coupled to the spray bar assembly and configured to cause the spray bar assembly to:
create a polishing foam using a polishing liquid, a surfactant, and a gas using the foam sprayer nozzle assembly; and
dispense, using the dispense arm, the polishing foam onto a polishing pad.

10. The spray bar assembly of claim 9, wherein the polishing liquid, the surfactant, and the gas are configured to produce a polishing foam when mixed in an inner volume of the nozzle body.

11. The spray bar assembly of claim 9, wherein the gas supply line delivers nitrogen gas (N₂) to an inner volume of the nozzle body.

12. The spray bar assembly of claim 9, wherein the polishing liquid supply line delivers a polishing mixture of a polishing liquid and a surfactant before mixing with the gas and before entering an inner volume of the nozzle body.

13. The spray bar assembly of claim 9, wherein the polishing foam comprises bubbles of the gas with bubble walls having the polishing liquid and the surfactant.

14. The spray bar assembly of claim 13, the bubble walls further comprising abrasive particles.

15. A method of polishing a substrate, comprising:
placing a substrate on a polishing pad of a polishing apparatus;
creating a polishing foam using a polishing liquid, a surfactant, and a gas;
dispensing the polishing foam onto the polishing pad; and
rotating the polishing pad to polish the substrate.

16. The method of claim 15, wherein the polishing foam is created using a foam sprayer nozzle assembly comprising a nozzle body, a polishing liquid supply line, a surfactant supply line, and a gas supply line.

17. The method of claim 16, wherein a polishing liquid from the polishing liquid supply line, a surfactant from the surfactant supply line, and a gas from the gas supply line mix in an inner volume of the nozzle body to create the polishing foam.

18. The method of claim 15, wherein the polishing foam is created using a foam sprayer nozzle assembly comprising a nozzle body, a polishing mixture supply line configured to deliver a polishing mixture having a polishing liquid and a surfactant, and a gas supply line.

19. The method of claim 18, wherein a polishing mixture of the polishing mixture supply line and a gas of the gas supply line mix in an inner volume of the nozzle body to create the polishing foam.

20. The method of claim 15, wherein the gas is nitrogen gas (N₂).
